(19) United States
(12) Patent Application Publication
(10) Pub. No.: US 2019/0204395 A1
(43) Pub. Date: Jul. 4, 2019

(54) HALL SENSOR ARRAY

(71) Applicant: TEXAS INSTRUMENTS INCORPORATED, Dallas, TX (US)

(72) Inventors: Archana VENUGOPAL, Dallas, TX (US); Benjamin Stassen COOK, Addison, TX (US); Nazila DADVAND, Richardson, TX (US); Luigi COLOMBO, Dalllas, TX (US)

(21) Appl. No.: 16/235,939

(22) Filed: Dec. 28, 2018

Related U.S. Application Data
(60) Provisional application No. 62/612,177, filed on Dec. 29, 2017.

(51) Int. Cl. G01R 33/07; G01R 15/20

(52) U.S. Cl. CPC G01R 33/072; G01R 15/202

(57) ABSTRACT

In described examples, a 3D magnetic sensing block includes a plurality of interconnected unit cells including at least a first unit cell formed of first interconnected conducting segments, and a second unit cell formed of second interconnected conducting segments. The plurality of interconnected unit cells forms a lattice. The first unit cell is a first sensing element, and the second unit cell is a second sensing element.

### CROSS-REFERENCE TO RELATED APPLICATION(S)

This application claims priority to U.S. Provisional Application No. 62/612,177, filed Dec. 29, 2017, which is hereby incorporated by reference.

### BACKGROUND

A Hall sensor (or Hall effect sensor) is a transducer that varies its output voltage in response to a magnetic field. Hall effect sensors are used for, for example, detecting magnetic fields, proximity switching, positioning, speed detection, and/or current sensing applications. Planar Hall sensors on graphene have recently been developed. However, these planar Hall sensors are inefficient. This issue in turn can lead to problems such as poor signal-to-noise ratio. Thus, in order to solve these problems, it is desirable to provide a Hall sensor that is able to overcome the above disadvantages. Advantages of aspects of the disclosure will become more fully apparent from the detailed description hereinbelow.

### SUMMARY

In one aspect of the disclosure, a three-dimensional (3D) magnetic sensing block includes a plurality of interconnected unit cells including at least a first unit cell formed of first interconnected conducting segments, and a second unit cell formed of second interconnected conducting segments. The plurality of interconnected unit cells forms a lattice. The first unit cell is a first sensing element, and the second unit cell is a second sensing element.

In another aspect of the disclosure, a method of forming a 3D magnetic sensing block includes forming a 3D addressable array, including by photo-initiating polymerization of a monomer in a 3D pattern of interconnected unit cells to form a polymer lattice (wherein the interconnected unit cells include at least a first unit cell formed of first interconnected polymer segments, and a second unit cell formed of second interconnected polymer segments); removing the unpolymerized monomer; coating the polymer lattice with a metal; removing the polymer lattice to leave a metal lattice; depositing graphitic carbon on the metal lattice; converting the graphitic carbon to graphene or carbon nanotubes; and removing the metal lattice to form the 3D addressable array having a plurality of 3D addressable unit cells including at least a first 3D addressable unit cell formed of first interconnected graphene or first carbon nanotube segments, and a second 3D addressable unit cell formed of second interconnected graphene or second carbon nanotube segments. The first 3D addressable unit cell is a first sensing element, and the second 3D addressable unit cell is a second sensing element.

### BRIEF DESCRIPTION OF THE DRAWINGS

For a detailed description of various examples, reference will now be made to the accompanying drawings in which:

FIG. 1A is a schematic drawing of a fabrication process for an organic polymeric microlattice (scaffold) prior to coating with electroless plating, in accordance with this disclosure;

FIG. 1B is a flowchart of a fabrication process for a lattice which may follow the fabrication process of FIG. 1A, in accordance with this disclosure;

FIG. 2 is a side view schematic of a 3D Hall sensor (or Hall sensor array), in accordance with this disclosure; and

FIG. 3 is a flowchart illustrating a method of forming a 3D magnetic sensing block, in accordance with this disclosure.

### DETAILED DESCRIPTION

In this description, the term “couple” or “couples” means either an indirect or direct wired or wireless connection. Thus, if a first device couples to a second device, that connection may be through a direct connection or through an indirect connection via other devices and connections. Also, in this description, the recitation “based on” means “based at least in part on.” Therefore, if X is based on Y, then X may be a function of Y and any number of other factors.

For purposes of this disclosure, the terms “film”, “coating”, “sheet”, “structure”, and “layer” (and derivatives thereof) may be used interchangeably.

For purposes of this disclosure, the term “lattice” may alternatively encompass “microlattice”, “nanolattice”, and “superlattice” (and derivatives thereof) and thus, may be used interchangeably.

A Hall sensor is a device used for, inter alia, detecting magnetic fields, proximity switching, positioning, speed detection, and/or current sensing applications. One application of a Hall sensor would be as a current sensor. Current flow through a conductor generates magnetic fields. A sensor placed close to this current-carrying lead can be used to detect the strength of a magnetic field generated, which in turn can be used to detect the magnitude of current.

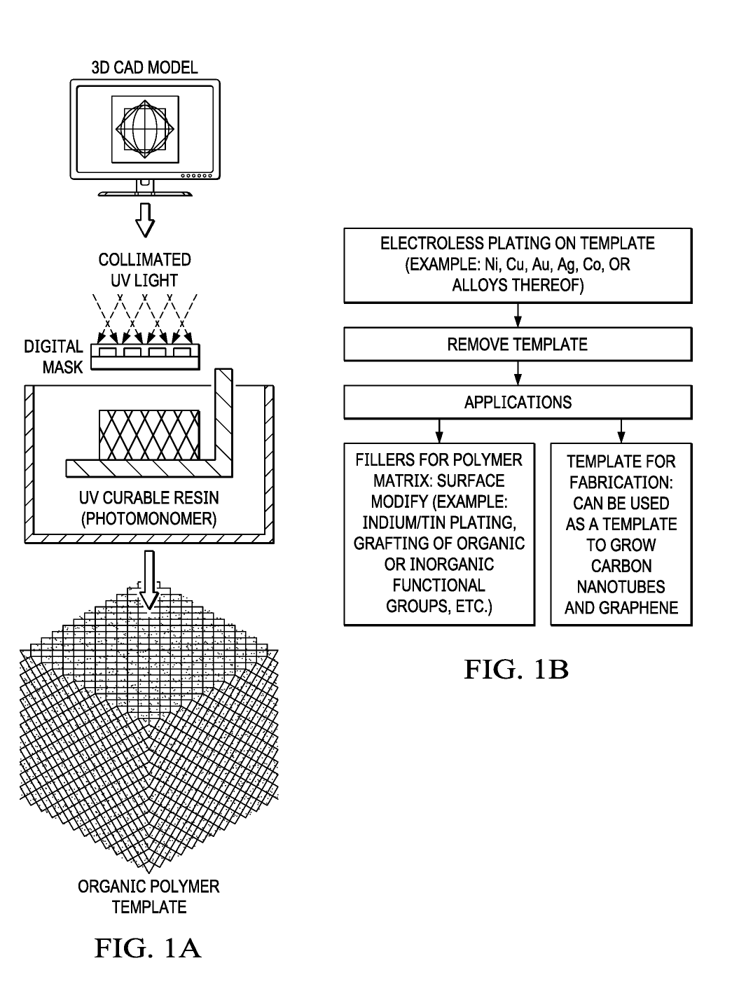

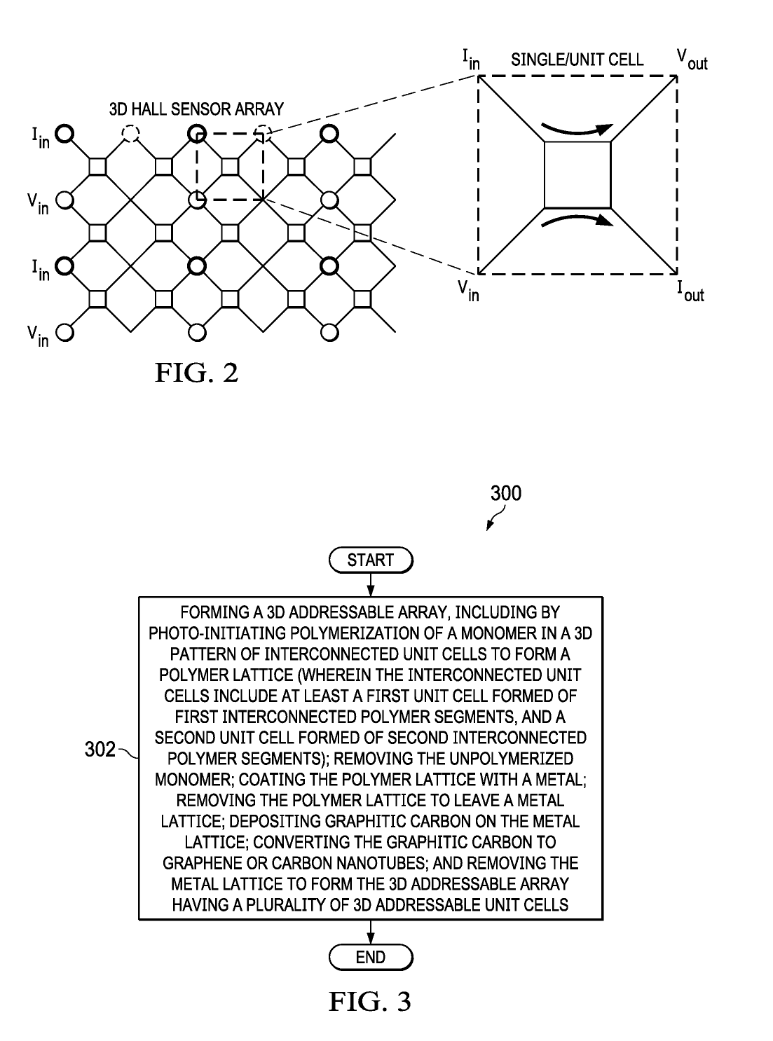

With reference to FIG. 2, shown is a side view schematic of a 3D Hall sensor (or Hall sensor array) employing a lattice (or lattice structure). The lattice employed in the Hall sensor may be formed, for example, as described below with reference to FIG. 1B.

It has been found that an organic/inorganic superstructure may be used as a template for the formation of a 3D metal superstructure that may then be used to grow graphitic carbon on the surface of the metal. The template may be fabricated through a self-propagating photopolymer waveguide technique (see, e.g., Xiaoyu Zheng et. al., Ultralight, Ultrastiff Mechanical Metamaterials; Science 344 (2014) 1373-1377 and T. A. Schaedler, et al., Ultralight Metallic Microlattices; Science 334 (2011) 962-965) in which an interconnected 3D photopolymer lattice may be produced upon exposure of an appropriate liquid photomonomer to collimated UV light through a specifically designed mask that contains openings with certain spacing and size. The fabricated microlattice may then be then coated by electroless copper or other suitable metal (e.g. Ni, Co, Au, Ag, Cu, and alloys thereof) followed by etching away the organic polymeric matrix (scaffold). The resulting metal-based microlattice may be then used as a template to grow the graphitic carbon. The thickness of the electroless plated metal may be controlled in the range of nanometer to micrometer by adjusting the plating time, temperature, and/or plating chemistry.

FIG. 1A schematically illustrates an exemplary fabrication process of an organic polymeric microlattice (scaffold) prior to coating with electroless plating.

The present disclosure employs a “periodically structured” graphene nanostructure. Conventional graphene structures are irregular and have much larger dimensions than those which may be achieved using the methodology disclosed herein.

The present process may be used to create a regular array, and the superstructure dimensions (unit cell) and structure may be optimized for strength, thermal and other fundamental properties.

There are several aspects of this procedure that are noteworthy:
it provides a regular structure with defined dimensions;
it has the ability to form very thin metal (e.g. Ni, Co, Cu, Ag, Au) microlattices;
it enables the formation of graphitic carbon on very thin metals by a surface-limited process for very thin metal wires or tubes.

The present process uses a polymeric structure as a template for such fabrication with the subsequent formation of a metal superstructure that may then be exposed to a hydrocarbon (e.g. methane, ethylene, acetylene, benzene) to form graphitic carbon, followed by etching of the metal from under the graphitic carbon using appropriate etchants such as, for example, FeCl₃ or potassium permanganate.

Collimated light through a photomask or multi-photon photography may be used in a photo-initiated polymerization to produce a polymer microlattice comprised of a plurality of unit cells. Exemplary polymers include polystyrene and poly(methyl methacrylate) (PMMA). Once polymerized in the desired pattern, the remaining un-polymerized monomer may be removed.

The polymer structure (polymer scaffold) may then be plated with a suitable metal using an electroless plating process.

Electroless nickel plating (EN) is an auto-catalytic chemical technique that may be used to deposit a layer of nickel-phosphorus or nickel-boron alloy on a solid workpiece, such as metal, plastic, or ceramic. The process relies on the presence of a reducing agent, for example hydrated sodium hypophosphite (NaPO₂H₂.H₂O) which reacts with the metal ions to deposit metal. Alloys with different percentages of phosphorus, ranging from 2-5 (low phosphorus) to up to 11-14 (high phosphorus) are possible. The metallurgical properties of the alloys depend on the percentage of phosphorus.

Electroless plating has several advantages over electroplating. Free from flux-density and power supply issues, it provides an even deposit regardless of workpiece geometry, and with the proper pre-plate catalyst, may deposit on non-conductive surfaces. In contradistinction, electroplating can only be performed on electrically conductive substrates.

Before performing electroless plating, the material to be plated must be cleaned by a series of chemicals; this is known as the pre-treatment process. Failure to remove unwanted “soils” from the part's surface results in poor plating. Each pre-treatment chemical must be followed by water rinsing (normally two to three times) to remove chemicals that may adhere to the surface. De-greasing removes oils from surfaces, whereas acid cleaning removes scaling.

Activation may be done with an immersion into a sensitizer/activator solution—for example, a mixture of palladium chloride, tin chloride, and hydrochloric acid. In the case of non-metallic substrates, a proprietary solution is often used.

The pre-treatment required for the deposition of metals on a non-conductive surface usually consists of an initial surface preparation to render the substrate hydrophilic. Following this initial step, the surface may be activated by a solution of a noble metal, e.g., palladium chloride. Electroless bath formation varies with the activator. The substrate is then ready for electroless deposition.

The reaction is accomplished when hydrogen is released by a reducing agent, normally sodium hypophosphite (with the hydrogen leaving as a hydride ion) or thiourea, and oxidized, thus producing a negative charge on the surface of the part. The most common electroless plating method is electroless nickel plating, although silver, gold and copper layers can also be applied in this manner.

In principle any hydrogen-based reducing agent can be used although the redox potential of the reducing half-cell must be high enough to overcome the energy barriers inherent in liquid chemistry. Electroless nickel plating most often employs hypophosphite as the reducer while plating of other metals like silver, gold and copper typically makes use of low-molecular-weight aldehydes.

A benefit of this approach is that the technique can be used to plate diverse shapes and types of surfaces.

As illustrated in FIG. 1B, the organic polymeric microlattice may be electrolessly plated with metal (e.g., comprising copper or nickel) followed by dissolving out the organic polymer scaffold. The fabricated metal-based microlattice is used as a template to synthesize a graphitic carbon superstructure. The metal may then be etched out to produce a graphene microstructure comprising a plurality of unit cells which are formed of interconnected graphene tubes.

As an alternative to or in addition to the above processes, the graphene lattices may be formed via any of the fabrication techniques (or portion(s) of the fabrication techniques thereof, including any pre-treatments) described in U.S. Provisional Application Ser. No. 62/611,347, filed Dec. 28, 2017, entitled “SP²-Bonded Carbon Structures”, all of which are hereby incorporated in this disclosure.

In an example, with any of the processes described above, a Cu-based microlattice template may be employed to grow graphene on the surface of the Cu by chemical vapor deposition (CVD) using methane or other appropriate C—H compounds at a temperature ranging from 700 to 1050° C.

With additional reference to FIG. 2, in the lattice, each block (i.e., single/unit cell) as indicated by the circular inset functions as a Hall element. More specifically, the lattice intercepts are active Hall elements, and the legs of the lattice extending from the lattice intercepts are contacts for current applications and voltage measurements which are described more fully below. An enlarged view of the circular inset is shown on the right side of FIG. 2. Each block comprises 3 pairs of legs described below. One of the pair of legs is in a direction inside and outside of the page and is therefore not shown in FIG. 2.

Each unit cell produces a Hall voltage. With reference to Lorentz force, sending in a current in a 3D homogenous magnetic field (i.e., in 3D/free space, such as provided via a lattice) on some of the tubes (i.e., when employing a lattice comprising CNTs), a Hall voltage is obtained on some of the other/remaining tubes. Since a 3D lattice is employed, one can selectively probe and send current in certain points and pull out at other points to thereby find a magnetic field anywhere in the free space of the lattice. In other words, by sending current in and out of one pin (or pair of legs) of the lattice and measuring voltage on the other two pins, a Hall voltage can be measured/pulled from any point in 3D space, thereby achieving a 3D addressable Hall sensor.

With this process, since a Hall voltage is only obtained due to the magnetic field that's perpendicular to the current, one can send in current in three different directions. In particular, when sending in x-direction current, the magnetic field component perpendicular to the x-direction can be obtained. When sending in y-direction current (to the same cell), the magnetic field component perpendicular to the y-direction can be obtained. And when sending in z-direction current (to the same cell), the magnetic field component perpendicular to the z-direction can be obtained. With this configuration and process, a 3D representation of the magnetic field is obtained.

With specific reference to the enlarged section in FIG. 2, the process includes sending Iᵢₙ and Iₒᵤₜ on every one of the pairs of legs and measuring voltage from the other two pairs of legs. The process would therefore be repeated in a 3-step measurement process.

The application of a 3D lattice structure allows for the ability to effectively have multiple such Hall elements connected in series as well as in parallel. In the view shown in FIG. 2, the magnetic field will be perpendicular to the structure (e.g., into or out of the page). Another advantage of employing a lattice structure as disclosed herein is that by way of rotation of the lattice, it is possible to detect magnetic fields in various directions. This ability negates the need to do process changes (e.g., with horizontal and vertical Si Hall sensors).

With additional reference to FIG. 2, in one aspect of the disclosure, a three-dimensional (3D) magnetic sensing block includes a plurality of interconnected unit cells including at least a first unit cell formed of first interconnected conducting segments, and a second unit cell formed of second interconnected conducting segments. The plurality of interconnected unit cells forms a lattice. The first unit cell is a first sensing element, and the second unit cell is a second sensing element.

In an example, the first and second sensing elements are Hall sensing elements.

In an example, the first and second interconnected conducting segments comprise graphene.

In an example, the first and second interconnected conducting segments comprise carbon nanotubes.

In an example, the first and second interconnected conducting segments comprise a metal or a metal coated with another metal.

In an example, the first and second interconnected conducting segments are hollow tubes.

In an example, the first and second interconnected conducting segments are tubes filled with a conducting material.

In an example, the first and second sensing elements are individually addressable in three dimensions.

In an example, the block is a magnetic field sensor configured to detect magnetic fields in three dimensions.

In an example, the block is a 3D addressable Hall sensor.

In an example, the first and second unit cells comprise three opposing pairs of connected legs in three different directions, and wherein a leg from one pair is arranged to receive current while current is drawn from the opposite leg of the one pair, while voltage is measurable at the other two pairs.

In an example, the first and second unit cells comprise six legs which comprise three opposing pairs of connected legs in three different directions, and wherein any leg from any pair of the three opposing pairs of connected legs is arranged to receive and output current, and voltage is measurable at any leg from any of the remaining pairs of the three opposing pairs of connected legs.

In an example, the three different directions are orthogonal from each other.

With reference to FIG. 3, in another aspect of the disclosure, a method 300 of forming a 3D magnetic sensing block includes forming a 3D addressable array, including by photo-initiating polymerization of a monomer in a 3D pattern of interconnected unit cells to form a polymer lattice (wherein the interconnected unit cells include at least a first unit cell formed of first interconnected polymer segments, and a second unit cell formed of second interconnected polymer segments); removing the unpolymerized monomer; coating the polymer lattice with a metal; removing the polymer lattice to leave a metal lattice; depositing graphitic carbon on the metal lattice; converting the graphitic carbon to graphene or carbon nanotubes; and removing the metal lattice to form the 3D addressable array having a plurality of 3D addressable unit cells (block 302) including at least a first 3D addressable unit cell formed of first interconnected graphene or first carbon nanotube segments, and a second 3D addressable unit cell formed of second interconnected graphene or second carbon nanotube segments. The first 3D addressable unit cell is a first sensing element, and the second 3D addressable unit cell is a second sensing element.

In an example of the method, the first and second sensing elements are Hall sensing elements.

In an example of the method, the first and second sensing elements are individually addressable in three dimensions.

In an example of the method, the block is a magnetic field sensor configured to detect magnetic fields in three dimensions.

In an example of the method, the block is a 3D addressable Hall sensor.

In an example of the method, the first and second 3D addressable unit cells comprise three opposing pairs of connected legs in three different directions, wherein a leg from one pair is arranged to receive current while current is drawn from the opposite leg of the one pair, while voltage is measurable at the other two pairs.

In an example of the method, the first and second 3D addressable unit cells comprise six legs which comprise three opposing pairs of connected legs in three different directions, and wherein any leg from any pair of the three opposing pairs of connected legs is arranged to receive and output current, and voltage is measurable at any leg from any of the remaining pairs of the three opposing pairs of connected legs.

In an example of the method, the three different directions are orthogonal from each other.

With graphene employed as the composition of the lattice for the Hall sensor, improvements in gate tune-ability, ambi-polar behavior, high mobility, and/or integrability in Si device flows are achieved. Also, with a 3D addressable Hall sensor as described in the examples above, a Hall sensor for gradient, vector-based Hall sensing having an improved signal-to-noise ratio is achieved.

In any of the examples above, the graphene employed as the material of the lattice (i.e., graphene lattice) could alternatively be replaced with CNTs (i.e., CNT lattice) or another conducting material comprising, for example, a metal or metal alloy. The above-mentioned processes of manufacturing the graphene lattice (or portions thereof) may be adjusted accordingly dependent on the material of the lattice employed. Steps in the above-mentioned processes may also be eliminated or added dependent on the material of the lattice employed. Such alternatives are considered to be within the spirit and scope of the disclosure, and may therefore utilize the advantages of the configurations and examples described above.

The method steps in any of the examples described herein are not restricted to being performed in any particular order. Also, structures mentioned in any of the method examples may utilize structures mentioned in any of the device examples. Such structures may be described in detail with respect to the device examples only but are applicable to any of the method examples.

Features in any of the examples described in this disclosure may be employed in combination with features in other examples described herein, and such combinations are considered to be within the spirit and scope of the present disclosure.

Modifications are possible in the described embodiments, and other embodiments are possible, within the scope of the claims.

What is claimed is:

1. A 3D magnetic sensing block, the block comprising:
a plurality of interconnected unit cells including at least a first unit cell formed of first interconnected conducting segments, and a second unit cell formed of second interconnected conducting segments, and wherein the plurality of interconnected unit cells forms a lattice;
wherein the first unit cell is a first sensing element, and the second unit cell is a second sensing element.

2. The block of claim 1, wherein the first and second sensing elements are Hall sensing elements.

3. The block of claim 1, wherein the first and second interconnected conducting segments comprise graphene.

4. The block of claim 1, wherein the first and second interconnected conducting segments comprise carbon nanotubes.

5. The block of claim 1, wherein the first and second interconnected conducting segments comprise a metal or a metal coated with another metal.

6. The block of claim 1, wherein the first and second interconnected conducting segments are hollow tubes.

7. The block of claim 1, wherein the first and second interconnected conducting segments are tubes filled with a conducting material.

8. The block of claim 1, wherein the first and second sensing elements are individually addressable in three dimensions.

9. The block of claim 8, wherein the block is a magnetic field sensor configured to detect magnetic fields in three dimensions.

10. The block of claim 8, wherein the block is a 3D addressable Hall sensor.

11. The block of claim 8, wherein the first and second unit cells comprise three opposing pairs of connected legs in three different directions, and wherein a leg from one pair is arranged to receive current while current is drawn from the opposite leg of the one pair, while voltage is measurable at the other two pairs.

12. The block of claim 8, wherein the first and second unit cells comprise six legs which comprise three opposing pairs of connected legs in three different directions, and wherein any leg from any pair of the three opposing pairs of connected legs is arranged to receive and output current, and voltage is measurable at any leg from any of the remaining pairs of the three opposing pairs of connected legs.

13. The block of claim 12, wherein the three different directions are orthogonal from each other.

14. A method of forming a 3D magnetic sensing block, the method comprising:
forming a 3D addressable array, including by:
photo-initiating polymerization of a monomer in a 3D pattern of interconnected unit cells to form a polymer lattice, wherein the interconnected unit cells include at least a first unit cell formed of first interconnected polymer segments, and a second unit cell formed of second interconnected polymer segments;
removing the unpolymerized monomer;
coating the polymer lattice with a metal;
removing the polymer lattice to leave a metal lattice;
depositing graphitic carbon on the metal lattice;
converting the graphitic carbon to graphene or carbon nanotubes; and
removing the metal lattice to form the 3D addressable array having a plurality of 3D addressable unit cells including at least a first 3D addressable unit cell formed of first interconnected graphene or first carbon nanotube segments, and a second 3D addressable unit cell formed of second interconnected graphene or second carbon nanotube segments;
wherein the first 3D addressable unit cell is a first sensing element, and the second 3D addressable unit cell is a second sensing element.

15. The method of claim 14, wherein the first and second sensing elements are Hall sensing elements.

16. The method of claim 14, wherein the first and second sensing elements are individually addressable in three dimensions.

17. The method of claim 16, wherein the block is a magnetic field sensor configured to detect magnetic fields in three dimensions.

18. The method of claim 16, wherein the block is a 3D addressable Hall sensor.

19. The method of claim 16, wherein the first and second 3D addressable unit cells comprise three opposing pairs of connected legs in three different directions, wherein a leg from one pair is arranged to receive current while current is drawn from the opposite leg of the one pair, while voltage is measurable at the other two pairs.

20. The block of claim 16, wherein the first and second 3D addressable unit cells comprise six legs which comprise three opposing pairs of connected legs in three different directions, and wherein any leg from any pair of the three opposing pairs of connected legs is arranged to receive and output current, and voltage is measurable at any leg from any of the remaining pairs of the three opposing pairs of connected legs.

21. The method of claim 20, wherein the three different directions are orthogonal from each other.
